(19) United States
(12) Patent Application Publication
(10) Pub. No.: US 2009/0134438 A1
(43) Pub. Date: May 28, 2009

(54) Image Sensor

(75) Inventors: Mamoru Arimoto, Ogaki-shi (JP); Ryu Shimizu, Mizuho-shi (JP); Hayato Nakashima, Anpachi-gun (JP); Kaori Misawa, Kaizu-shi (JP)

Correspondence Address: DITTHAVONG MORI & STEINER, P.C., 918 Prince St., Alexandria, VA, 22314, US

(73) Assignee: Sanyo Electric Co., Ltd., Osaka (JP)

(21) Appl. No.: 12/276,648

(22) Filed: Nov. 24, 2008

(30) Foreign Application Priority Data
Nov. 26, 2007 (JP) 2007-304147

(51) Int. Cl. H01L 27/146

(52) U.S. Cl. 257/292; 257/E27.133

(57) ABSTRACT

A CMOS image sensor includes an impurity region provided under at least the first electrode, the second electrode and the third electrode for forming a path through which the signal charges transfer, wherein the impurity concentration of a region of the impurity region corresponding to a portion located under the first electrode is higher than the impurity concentration of a region of the impurity region corresponding to each of portions located under at least the second electrode and the third electrode.

### CROSS-REFERENCE TO RELATED APPLICATIONS

The priority application number JP2007-304147, Image Sensor, Nov. 26, 2007, Mamoru Arimoto, Ryu Shimizu, Hayato Nakashima, Kaori Misawa, upon which this patent application is based is hereby incorporated by reference.

### BACKGROUND OF THE INVENTION

1. Field of the Invention

The present invention relates to an image sensor, and more particularly, it relates to an image sensor comprising an electrode for forming an electric field storing signal charges.

2. Description of the Background Art

An image sensor comprising an electrode for forming an electric field storing electrons (signal charges) is known in general.

A conventional general CMOS image sensor comprising a photodiode converting light incident by photoelectric conversion to electrons, an electrode for reading charges stored in the photodiode and a floating diffusion region for converting stored electrons to electric signals is disclosed in a non-patent document, Basics and Applications of a CCD/CMOS Image Sensor (pp. 189-191) by Kazuya Yonemoto, CQ publishing, (published in Feb. 1, 2004).

### SUMMARY OF THE INVENTION

An image sensor according to a first aspect of the present invention comprises a charge storage portion for storing and transferring signal charges, a first electrode for storing the signal charges in the charge storage portion, a second electrode for transferring the signal charges to the charge storage portion, a voltage conversion portion for converting the signal charges to a voltage, a third electrode provided between the first electrode and the voltage conversion portion for transferring the signal charges stored in the charge storage portion to the voltage conversion portion and an impurity region provided under at least the first electrode, the second electrode and the third electrode for forming a path through which the signal charges transfer, wherein the impurity concentration of a region of the impurity region corresponding to a portion located under the first electrode is higher than the impurity concentration of a region of the impurity region corresponding to each of portions located under at least the second electrode and the third electrode.

A sensor unit according to a second aspect of the present invention comprises a charge storage portion for storing and transferring signal charges, a first electrode for storing the signal charges in the charge storage portion, a second electrode for transferring the signal charges to the charge storage portion, a voltage conversion portion for converting the signal charges to a voltage, a third electrode provided between the first electrode and the voltage conversion portion for transferring the signal charges stored in the charge storage portion to the voltage conversion portion and an impurity region provided under at least the first electrode, the second electrode and the third electrode for forming a path through which the signal charges transfer, wherein the impurity concentration of a region of the impurity region corresponding to a portion located under the first electrode is higher than the impurity concentration of a region of the impurity region corresponding to each of portions located under at least the second electrode and the third electrode.

A CMOS image sensor according to a third aspect of the present invention comprises a charge storage portion for storing and transferring signal charges, a first electrode for storing the signal charges in the charge storage portion, a second electrode for transferring the signal charges to the charge storage portion, a voltage conversion portion for converting the signal charges to a voltage, a third electrode provided between the first electrode and the voltage conversion portion for transferring the signal charges stored in the charge storage portion to the voltage conversion portion, a charge increasing portion for increasing the signal charges stored in the charge storage portion and an impurity region provided under at least the first electrode, the second electrode and the third electrode for forming a path through which the signal charges transfer, wherein the first electrode, the second electrode, the third electrode and the charge increasing portion are provided in a pixel, and the impurity concentration of a region of the impurity region corresponding to a portion located under the first electrode is higher than the impurity concentration of a region of the impurity region corresponding to each of portions located under at least the second electrode and the third electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of a CMOS image sensor according to a first embodiment of the present invention;

FIG. 2 is a sectional view in the CMOS image sensor according to the first embodiment;

FIG. 3 is a potential diagram in the CMOS image sensor according to the first embodiment;

FIG. 4 is a plan view showing a pixel of the CMOS image sensor according to the first embodiment;

FIG. 5 is a circuit diagram showing a circuit structure of the active CMOS image sensor according to the first embodiment;

FIG. 6 is a signal waveform diagram for illustrating an electron transferring operation of the CMOS image sensor according to the first embodiment;

FIG. 7 is a potential diagram for illustrating the electron transferring operation of the CMOS image sensor according to the first embodiment;

FIG. 8 is a signal waveform diagram for illustrating an electron multiplying operation of the CMOS image sensor according to the first embodiment;

FIG. 9 is a potential diagram for illustrating the electron multiplying operation of the CMOS image sensor according to the first embodiment;

FIG. 10 is a signal waveform diagram for illustrating an electron transferring operation of a CMOS image sensor according to a second embodiment;

FIG. 11 is a potential diagram for illustrating the electron transferring operation of the CMOS image sensor according to the second embodiment;

FIG. 12 is a signal waveform diagram for illustrating an electron multiplying operation of the CMOS image sensor according to the second embodiment;

FIG. 13 is a potential diagram for illustrating the electron multiplying operation of the CMOS image sensor according to the second embodiment;

FIG. 14 is a potential diagram for illustrating a modification of the CMOS image sensor according to the first and second embodiments; and

FIG. 15 is a diagram for illustrating a sensor unit as a modification of the first and second embodiments.

### DESCRIPTION OF THE PREFERRED EMBODIMENTS

Embodiments of the present invention will be hereinafter described with reference to the drawings.

### First Embodiment

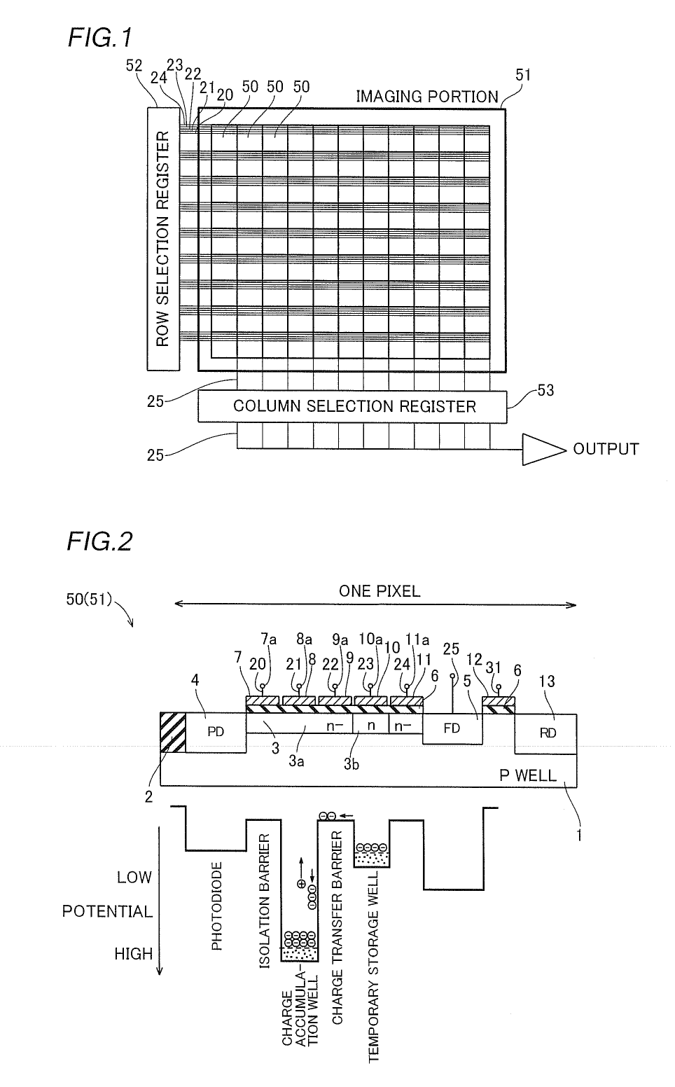

A structure of a CMOS image sensor according to a first embodiment will be now described with reference to FIGS. 1 to 5. The first embodiment of the present invention is applied to an active CMOS image sensor employed as an exemplary image sensor.

The CMOS image sensor according to the first embodiment comprises an imaging portion 51 including a plurality of pixels 50 arranged in the form of a matrix, a row selection register 52 and a column selection register 53, as shown in FIG. 1.

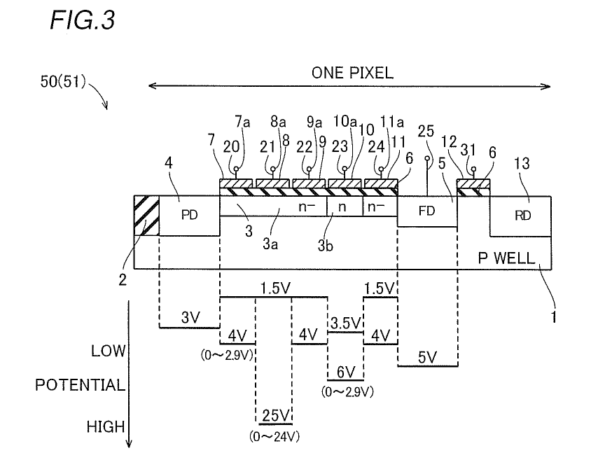

As to the sectional structure of the pixels 50 of the CMOS image sensor according to the first embodiment, element isolation regions 2 for isolating the pixels 50 from each other are formed on a surface of a p-type well region 1 formed on a surface of an n-type silicon substrate (not shown), as shown in FIGS. 2 and 3. On the surface of the p-type well region 1 provided with each pixel 50 enclosed with an element isolation region 2, a photodiode (PD) portion 4 and a floating diffusion (FD) region 5 consisting of an n-type impurity region are formed at a prescribed interval, to hold a transfer channel 3 including an n⁻-type impurity region therebetween. The transfer channel 3 and the FD region 5 are examples of the “impurity region” and the “voltage conversion portion” in the present invention respectively. The PD portion 4 is an example of the “photoelectric conversion portion” in the present invention.

The PD portion 4 has a function of generating electrons in response to the quantity of incident light and storing the generated electrons. The PD portion 4 is formed to be adjacent to the corresponding element isolation region 2 as well as to the transfer channel 3. The FD region 5 has a function of holding a charge signal formed by transferred electrons and converting the charge signal to a voltage. The FD region 5 is formed to be adjacent to the corresponding the transfer channel 3. Thus, the FD region 5 is opposed to the PD portion 4 through the transfer channel 3.

A gate insulating film 6 made of SiO₂ is formed on an upper surface of the transfer channel 3. A transfer gate electrode 7, a multiplier gate electrode 8, a transfer gate electrode 9, a storage gate electrode 10 and a read gate electrode 11 are formed on the gate insulating film 6 in this order from the side of the PD portion 4 toward the side of the FD region 5. A reset gate electrode 12 is formed on a position holding the FD region 5 between the read gate electrode 11 and the reset gate electrode 12 through the gate insulating film 6 and a reset drain region 13 is formed on a position opposed to the FD region 5 with the reset gate electrode 12 therebetween. The electron multiplying portion 3a is provided on a region of the transfer channel 3 located under the multiplier gate electrode 8, and the electron storage portion 3b is provided on a region of the transfer channel 3 located under the storage gate electrode 10. The transfer gate electrode 7, the multiplier gate electrode 8, the transfer gate electrode 9, the storage gate electrode 10 and the read gate electrode 11 are examples of the “fifth electrode”, the “fourth electrode”, the “second electrode”, the “first electrode” and the “third electrode” in the present invention respectively. The electron multiplying portion 3a is an example of the “charge increasing portion” in the present invention, and the electron storage portion 3b is an example of the “charge storage portion” in the present invention.

The transfer gate electrode 7 is formed between the PD portion 4 and the multiplier gate electrode 8. The read gate electrode 11 is formed between the storage gate electrode 10 and the FD region 5. The read gate electrode 11 is formed to be adjacent to the FD region 5.

According to the first embodiment, an impurity concentration of the region (electron storage portion 3b) of the transfer channel 3 located under the storage gate electrode 10 is higher than the impurity concentration of each of regions of the transfer channel 3 located under the remaining electrodes other than the storage gate electrode 10. More specifically, under a condition where the gate insulating film 6 has a thickness of about 50 nm, for example, a peak concentration of the impurity in the impurity region (transfer channel 3) located under each of the remaining electrodes other than the storage gate electrode 10 is about 8.5×10¹⁶ cm⁻³, while a peak concentration of the impurity in the impurity region (electron storage portion 3b) located under the storage gate electrode 10 is about 2.5×10¹⁷ cm⁻³. For example, arsenic (As) is implanted as the impurity, and a depth of the peak concentration is located at a position of about 0.1 μm from a surface of the transfer channel 3. Thus, a potential of the region of the transfer channel 3 located under the storage gate electrode 10 is rendered higher than that of the region of the transfer channel 3 located under each of the remaining electrodes other than the storage gate electrode 10, when the same level signal is supplied (the same voltage is applied) to the electrodes respectively.

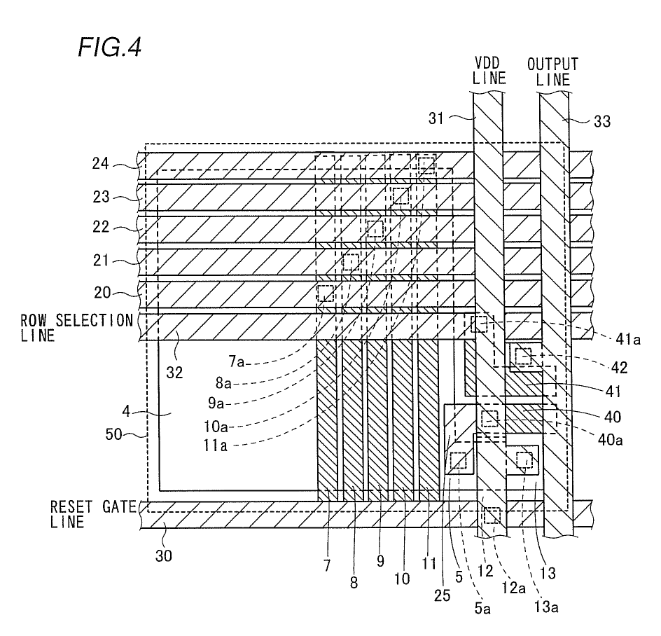

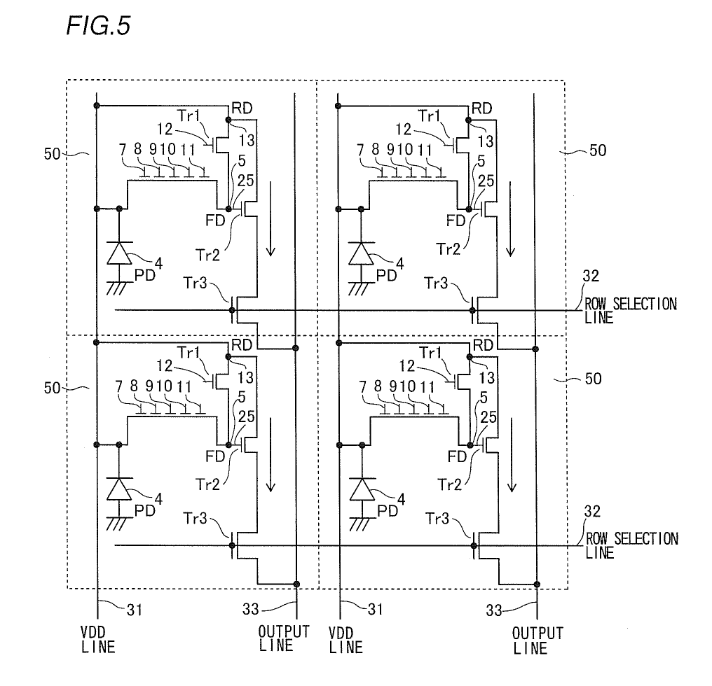

As shown in FIGS. 3 and 4, wiring layers 20, 21, 22, 23 and 24 supplying clock signals φ1, φ2, φ3, φ4 and φ5 for voltage control are electrically connected to the transfer gate electrode 7, the multiplier gate electrode 8, the transfer gate electrode 9, the storage gate electrode 10 and the read gate electrode 11 through contact portions 7a, 8a, 9a, 10a and 11a respectively. The wiring layers 20, 21, 22, 23 and 24 are formed every row, and electrically connected to the transfer gate electrodes 7, the multiplier gate electrodes 8, the transfer gate electrodes 9, the storage gate electrodes 10 and the read gate electrodes 11 of the plurality of pixels 50 forming each row respectively. A signal line 25 for extracting a signal through a contact portion 5a is electrically connected to each of the FD region 5.

In each pixel, when ON-state (high-level) clock signals φ1, φ3, φ4 and φ5 are supplied to the transfer gate electrodes 7 and 9 and the storage gate electrode 10 and the read gate electrode 11 through the wiring layers 20, 22, 23 and 24 respectively, voltages of about 2.9 V are applied to the transfer gate electrodes 7 and 9, the storage gate electrode 10 and the read gate electrode 11, as shown in FIG. 3. Each of the voltages (about 2.9 V) applied when supplying the ON-state (high-level) clock signals φ1, φ3, φ4 and φ5 to the transfer gate electrodes 7 and 9 and the storage gate electrode 10 and the read gate electrode 11 respectively is an example of the “second voltage” in the present invention.

According to the first embodiment, the regions of the transfer channel located under the transfer gate electrodes 7 and 9 and the read gate electrode 11 respectively are controlled to potentials of about 4 V and the region (electron storage portion 3b) of the transfer channel 3 located under the storage gate electrode 10 having an high concentration is controlled to a potential of about 6 V, when the voltages of about 2.9 V are applied (high-level clock signals are supplied) to the transfer gate electrodes 7 and 9, the storage gate electrode 10 and the read gate electrode 11 respectively.

When an ON-state (high-level) clock signal φ2 is supplied to the multiplier gate electrode 8 through the wiring layer 21, a voltage of about 24 V is applied to the multiplier gate electrode 8. Thus, the region of the transfer channel 3 located under the multiplier gate electrode 8 is controlled to a high potential of about 25 V when the ON-state (high-level) clock signal φ2 is supplied to the multiplier gate electrode 8. The voltage applied when supplying the ON-state (high-level) clock signal φ2 to the multiplier gate electrode 8 is an example of the “third voltage” in the present invention.

When OFF-state (low-level) clock signals φ1, φ2, φ3, φ4 and φ5 are supplied to the transfer gate electrode 7, the multiplier gate electrode 8, the transfer gate electrode 9, the storage gate electrode 10 and the read gate electrode 11 respectively, voltages of about 0 V (OFF-state voltages) are applied to the transfer gate electrode 7, the multiplier gate electrode 8, the transfer gate electrode 9 and the storage gate electrode 10 and the read gate electrode 11. At this time, according to the first embodiment, the regions of the transfer channel 3 located under the transfer gate electrode 7, the multiplier gate electrode 8, the transfer gate electrode 9 and the read gate electrode 11 are controlled to potentials of about 1.5 V, and the potential of the region (electron storage portion 3b) of the transfer channel 3 located under the storage gate electrode 10 having a high concentration is controlled to a potential of about 3.5 V. Each of the voltages (about 0 V) applied when supplying the OFF-state (low-level) clock signals φ1, φ2, φ3, φ4 and φ5 to each of the electrodes is an example of the “first voltage” in the present invention.

According to the first embodiment, the potential (about 3.5 V) of the storage gate electrode 10 in supplying the OFF-state clock signal φ4 to the storage gate electrode 10 is rendered higher than the potentials (about 1.5 V) of the transfer channel 3 located under the transfer gate electrode 9 and the read gate electrode 11 in supplying the OFF-state clock signals φ3 and 5 to the transfer gate electrode 9 and the read gate electrode 11. The potential (about 3.5 V) of the storage gate electrode 10 in supplying the OFF-state clock signal φ4 to the storage gate electrode 10 is rendered lower than the potentials (about 4 V) of the transfer channel 3 located under the transfer gate electrode 9 and the read gate electrode 11 in supplying the ON-state clock signals φ3 and φ5 to the transfer gate electrode 9 and the read gate electrode 11.

The FD region 5 is controlled to a potential of about 5 V. The reset drain region 13 is controlled to a potential of about 5 V and has a function as an ejecting portion of electrons held in the FD region 5.

The transfer gate electrode 7 has a function of transferring electrons generated by the PD portion 4 to the electron multiplying portion 3a located on the region of the transfer channel 3 located under the multiplier gate electrode 8 through the region of the transfer channel 3 located under the transfer gate electrode 7 by supplying the ON-state signal to the transfer gate electrode 7. The region of the transfer channel 3 located under the transfer gate electrode 7 has a function as an isolation barrier dividing the PD portion 4 and the region (electron multiplying portion 3a) of the transfer channel 3 located under the multiplier gate electrode 8 from each other when the OFF-state (low-level) clock signal φ1 is supplied to the transfer gate electrode 7.

A high electric field is applied to the electron multiplying portion 3a located on the region of the transfer channel 3 located under the multiplier gate electrode 8 by supplying the ON-state signal to the multiplier gate electrode 8. Then the speed of the electrons transferred from the PD portion 4 through the region of the transfer channel 3 located under the transfer gate electrode 7 is increased by the high electric field generated in the electron multiplying portion 3a and the electrons transferred from the PD portion 4 are multiplied by impact ionization with atoms in the impurity region.

The transfer gate electrode 9 has a function of transferring the electrons between the region (electron multiplying portion 3a) of the transfer channel 3 located under the multiplier gate electrode 8 and the electron storage portion 3b provided on the region of the transfer channel 3 located under the storage gate electrode 10 when the ON-state signal is supplied. When the OFF-state signal is supplied to the transfer gate electrode 9, on the other hand, the transfer gate electrode 9 functions as a charge transfer barrier for suppressing transfer of the electrons between the electron multiplying portion 3a located under the multiplier gate electrode 8 and the electron storage portion 3b located under the storage gate electrode 10.

The read gate electrode 11 has a function of transferring the electrons stored in the region (electron storage portion 3b) of the transfer channel 3 located under the storage gate electrode 10 to the FD region 5 by being supplied with the ON-state (high-level) signal. Further, the read gate electrode 11 has a function of dividing the region (electron storage portion 3b) of the transfer channel 3 located under the storage gate electrode 10 and the FD region 5 from each other when the OFF-state (low-level) signal is supplied to the read gate electrode 11.

As shown in FIGS. 4 and 5, each pixel 50 includes the transfer gate electrode 7, the multiplier gate electrode 8, the transfer gate electrode 9, the storage gate electrode 10, the read gate electrode 11, a reset gate transistor Tr1 having the reset gate electrode 12, an amplification transistor Tr2 and a pixel selection transistor Tr3. The PD portion 4 is connected to the transfer gate electrode 7. A reset gate line 30 is connected to the reset gate electrode 12 of the reset gate transistor Tr1 through a contact portion 12a, to supply a reset signal. The drain (reset drain 13) of the reset gate transistor Tr1 is connected to a power supply potential (VDD) line 31 through a contact portion 13a. The FD region 5 constituting a source of the reset gate transistor Tr1 and a source of the read gate electrode 11 and a gate 40 of the amplification transistor Tr2 are connected with each other by the signal line 25 through the contact portions 5a and a contact portion 40a. A source of the amplification transistor Tr2 is connected to a drain of the pixel selection transistor Tr3. The pixel selection transistor Tr3 has a gate 41 connected to a row selection line 32 through a contact portion 41a and a source connected to an output line 33 through a contact portion 42.

The CMOS image sensor according to the first embodiment is so formed as to reduce the number of wires and the number of transistors for decoding by the aforementioned circuit structure. Thus, the overall CMOS image sensor can be downsized. In this circuit structure, the read gate electrodes 11 are on-off controlled every row, while the remaining gate electrodes other than the read gate electrodes 11 are simultaneously on-off controlled with respect to the overall pixels 50.

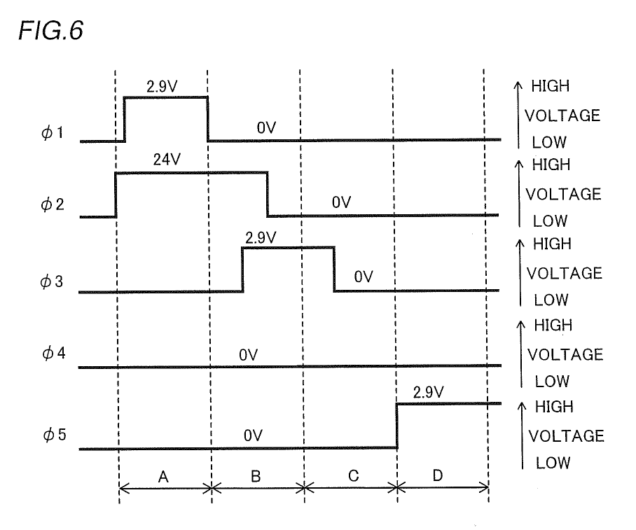

An electron transferring operation and an electron multiplying operation of the CMOS image sensor according to the first embodiment will be now described with reference to FIGS. 6 to 9.

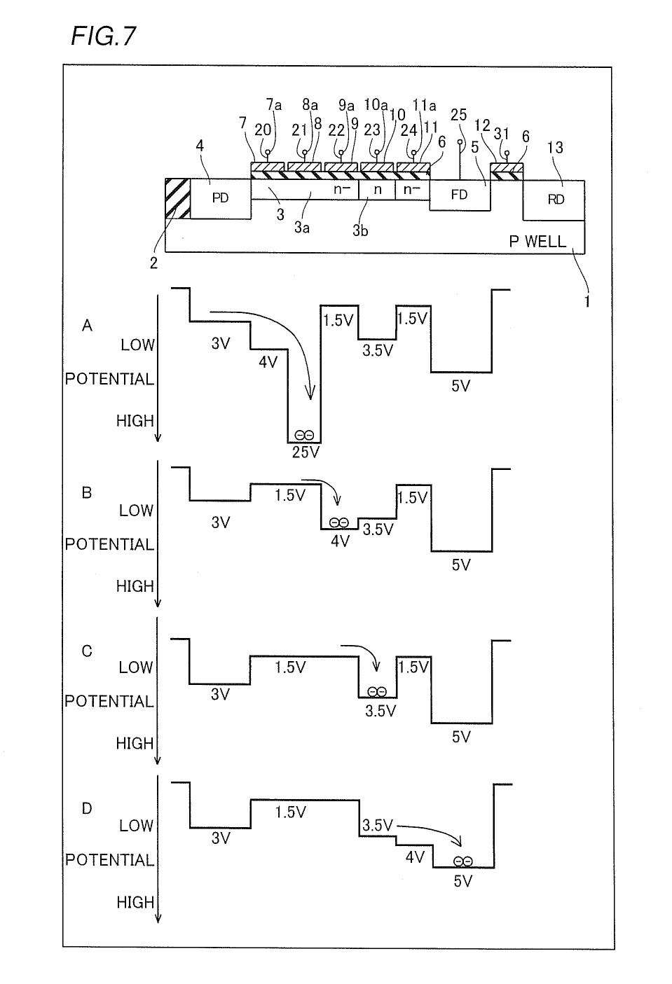

When light is incident upon the PD portion 4, the electrons are generated in PD portion 4 by photoelectric conversion. In a period A shown in FIGS. 6 and 7, a voltage of about 2.9 is applied to the transfer gate electrode 7 after a voltage of about 24 V is applied to the multiplier gate electrode 8. Thus, the potential of the region of the transfer channel 3 located under the transfer gate electrode 7 is controlled to a potential of about 4 in the state where the potential of the region of the transfer channel 3 located under the multiplier gate electrode 8 is controlled to a high potential of about 25 V. At this time, electrons generated by the PD portion 4 (about 3 V) are transferred to the region (electron multiplying portion 3a) of the transfer channel 3 located under the multiplier gate electrode 8, having a higher potential (about 25 V), through the region (about 4V) of the transfer channel 3 located under the transfer gate electrode 7, and are multiplied by impact ionization in the electron multiplying portion 3a.

In a period B, a voltage of about 2.9 V is applied to the transfer gate electrode 9 and a voltage of about 0 V is thereafter applied to the multiplier gate electrode 8. Thus, electrons are transferred from the electron multiplying portion 3a (about 1.5 V) under the multiplier gate electrode 8 to the region of the transfer channel 3 located under the transfer gate electrode 9 having a higher potential (about 4V). In a period C, a voltage of about 0 V is thereafter applied to the transfer gate electrode 9. Thus, electrons are transferred from the region (about 1.5 V) of the transfer channel 3 located under the transfer gate electrode 9 to the region (electron storage portion 3b) of the transfer channel 3 located under the storage gate electrode 10, having a higher potential (about 3.5 V). At this time, according to the first embodiment, electrons are stored in the electron storage portion 3b in the state of controlling so as to applying the OFF-state voltage to each electrode.

In a period D, a voltage of about 2.9 V is applied to the read gate electrode 11, to control the potential of the region of the transfer channel 3 located under the read gate electrode 11 to a potential of about 4 V. At this time, the region (electron storage portion 3b) of the transfer channel 3 located under the storage gate electrode 10 is controlled to a potential of about 3.5 V, and hence electrons are transferred to the FD region 5 controlled to a higher potential through the region (about 4V) of the transfer channel 3 located under the read gate electrode 11. Thus, the electron transferring operation is completed.

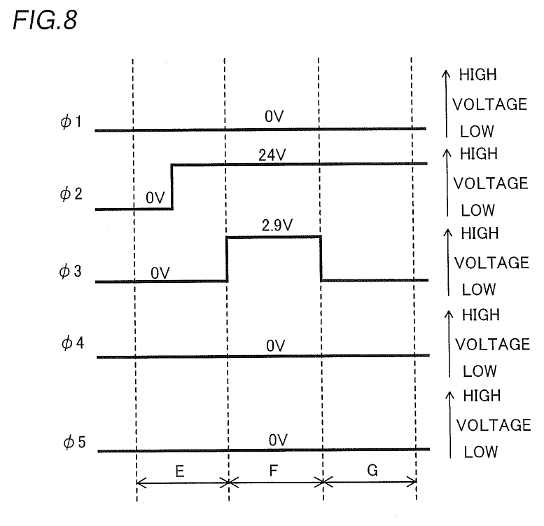

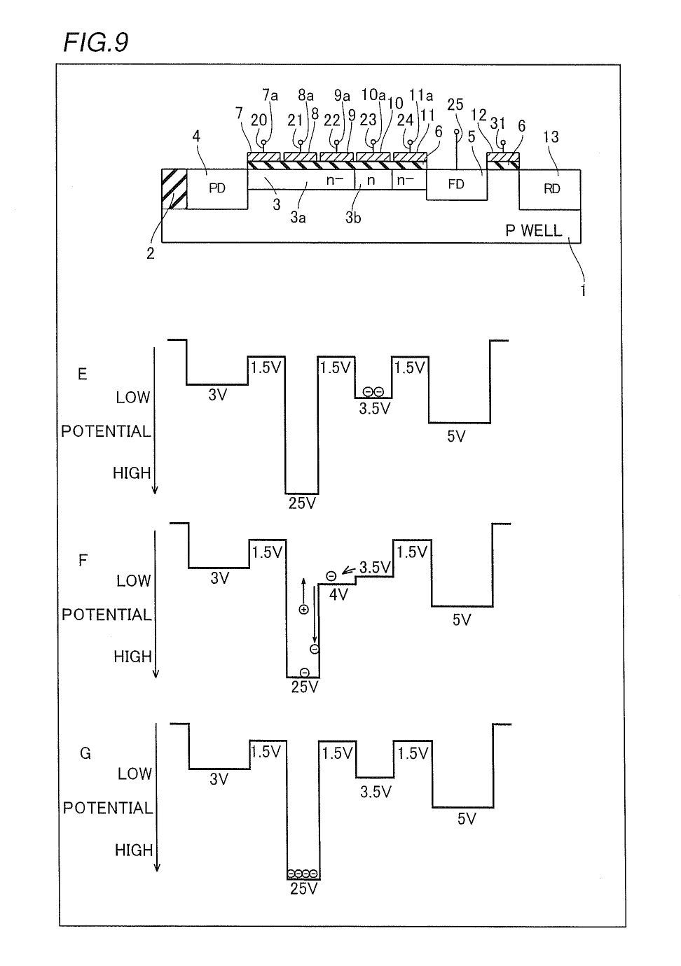

In the electron multiplying operation, the operations of the periods A to C in FIGS. 6 and 7 are performed, to a period E shown in FIGS. 8 and 9 and bring the transfer gate electrode 9 into an ON-state in a period F, in the state where the region (electron storage portion 3b) of the transfer channel 3 located under the storage gate electrode 10 stores electrons. Thus, the region (electron multiplying portion 3a) of the transfer channel 3 located under the multiplier gate electrode 8 is controlled to a potential of about 25 V and the region of the transfer channel 3 located under the transfer gate electrode 9 is thereafter controlled to a potential of about 4 V. At this time, according to the first embodiment, the storage gate electrode 10 is maintained in an OFF-state so that the potential of the region (electron storage portion 3b) of the transfer channel 3 located under the storage gate electrode 10 is maintained at about 3.5 V. Therefore, electrons stored in the electron storage portion 3b are transferred to the region (electron multiplying portion 3a) of the transfer channel 3 located under the multiplier gate electrode 8, having a higher potential (about 25 V), through the region (about 4V) of the transfer channel 3 located under the transfer gate electrode 9. Thus, according to the first embodiment, the operations of transferring and multiplying the electrons stored in the region (electron storage portion 3b) of the transfer channel 3 located under the storage gate electrode 10 are performed in the state where the OFF-state signal is still supplied to the storage gate electrode 10.

The electrons are transferred to the electron multiplying portion 3a to be multiplied in the aforementioned manner. The transfer gate electrode 9 is brought into an OFF-state in a period G, thereby completing the electron multiplying operation. The aforementioned operation in the periods A to C and the periods E to G (electron transferring operation between the electron multiplying portion 3a and the electron storage portion 3b) is controlled to be performed a plurality of times (about 400 times, for example), whereby the electrons transferred from the PD portion 4 are multiplied to about 2000 times. A charge signal by thus multiplied and stored electrons is read as a voltage signal through the FD region 5 and the signal line 25 by the aforementioned read operation.

According to the first embodiment, as hereinabove described, the impurity concentration of the region (electron storage portion 3b) of the transfer channel 3 located under the storage gate electrode 10 is rendered higher than that of the region of the transfer channel 3 located under each of the remaining electrodes other than the storage gate electrode 10, whereby the potential of the electron storage portion 3b is higher than that of the region of the transfer channel 3 located under each of the remaining electrodes when applying the same voltage (supplying the same level signal) to the remaining electrodes respectively and hence the larger number of electrons can be held. Therefore, the amount of signals to read noise is increased by multiplying electrons, and hence a signal-to-noise ratio in low level illuminance can be improved. Additionally, the multiplied electrons can be held and hence noise can be inhibited from increase resulting from increase in the ratio of noise to signals in the signal-to-noise ratio.

According to the aforementioned first embodiment, the potential (about 3.5 V) of the region (electron storage portion 3b) of the transfer channel 3 located under the storage gate electrode 10 in supplying the OFF-state clock signal φ4 thereto is rendered higher than the potentials (about 1.5 V) of the regions of the transfer channel 3 located under the transfer gate electrode 9 and the read gate electrode 11 in supplying the OFF-state clock signals φ3 and φ5 thereto, whereby electrons can be held in the electron storage portion 3b without bringing the storage gate electrode 10 into an ON-state. At this time, the potentials (about 1.5 V) of the regions of the transfer channel 3 located under the transfer gate electrode 9 and the read gate electrode 11 are lower than the potential (about 3.5 V) of the electron storage portion 3b, and hence the height of a potential barrier between the region of the transfer channel 3 located under the transfer gate electrode 9 and the electron storage portion 3b and the height of a potential barrier between the region of the transfer channel 3 located under the read gate electrode 11 and the electron storage portion 3b are increased. Therefore, electrons can be reliably inhibited from moving from the electron storage portion 3b. Further, electrons can be held in the state where the storage gate electrode 10 remains in the OFF-state. In other words, electrons can be reliably held in the state of applying no voltage to the storage gate electrode 10.

According to the aforementioned first embodiment, the potential (about 3.5 V) of the region (electron storage portion 3b) of the transfer channel 3 located under the storage gate electrode 10 in supplying the OFF-state signal thereto is rendered lower than the potential (about 4 V) of the region of the transfer channel 3 located under the read gate electrode 11 in supplying the ON-state signal thereto, whereby the potential difference between the electron storage portion 3b in the OFF-state and the FD region 5 can be formed when the read gate electrode 11 is in the ON-state, and electrons can be further easily transferred. In other words, a transfer effieciency of electrons can be increased by the potential difference between the electron storage portion 3b in the OFF-state and the FD region 5.

According to the aforementioned first embodiment, the potential (about 3.5 V) of the region (electron storage portion 3b) of the transfer channel 3 located under the storage gate electrode 10 in supplying the OFF-state clock signal φ4 thereto is rendered lower than the potential (about 4 V) of the region of the transfer channel 3 located under the transfer gate electrode 9 in supplying the ON-state clock signal φ3 thereto, whereby electrons can be transferred to the electron multiplying portion 3a while remaining the storage gate electrode 10 in the OFF-state, and hence the electrons stored in the electron storage portion 3b can be easily multiplied.

According to the aforementioned first embodiment, the electron multiplying operation by transferring electrons from the electron storage portion 3b to the electron multiplying portion 3a and the electron transferring operation by transferring electrons from the electron multiplying portion 3a to the electron storage portion 3b are alternately repeatedly performed in the state of supplying the OFF-state signal to the storage gate electrode 10, whereby both operations of the electron transferring operation and the electron multiplying operation can be performed while remaining the storage gate electrode 10 in the OFF-state. Therefore, control can be inhibited from complication.

According to the aforementioned first embodiment, the regions of the transfer channel 3 located under the transfer gate electrode 7, the multiplier gate electrode 8, the transfer gate electrode 9 and the read gate electrode 11 have the same impurity concentration, whereby the potentials of the transfer channel 3 located under the transfer gate electrode 7, the multiplier gate electrode 8, the transfer gate electrode 9 and the read gate electrode 11 are the same when the same voltage is applied to the respective electrodes. In other words, the potential changes of the regions of the transfer channel 3 located under the respective electrodes when applying the ON-state voltages and the OFF-state voltages to the respective electrodes are also the same, and hence the electron transferring operation can be easily controlled.

### Second Embodiment

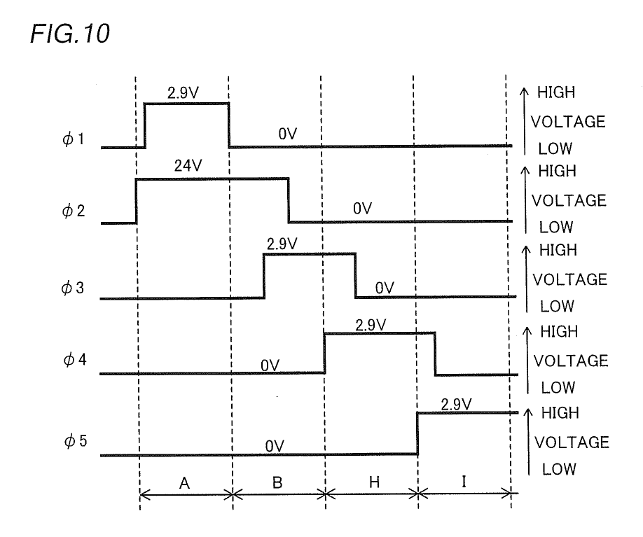

Referring to FIGS. 10 to 13, an electron transferring operation and an electron multiplying operation of a CMOS image sensor according to a second embodiment are performed by supplying an ON-state signal to a storage gate electrode 10 in the structure of the CMOS image sensor according to the aforementioned first embodiment. The structure of the CMOS image sensor according to the second embodiment is similar to that of the CMOS image sensor according to the first embodiment.

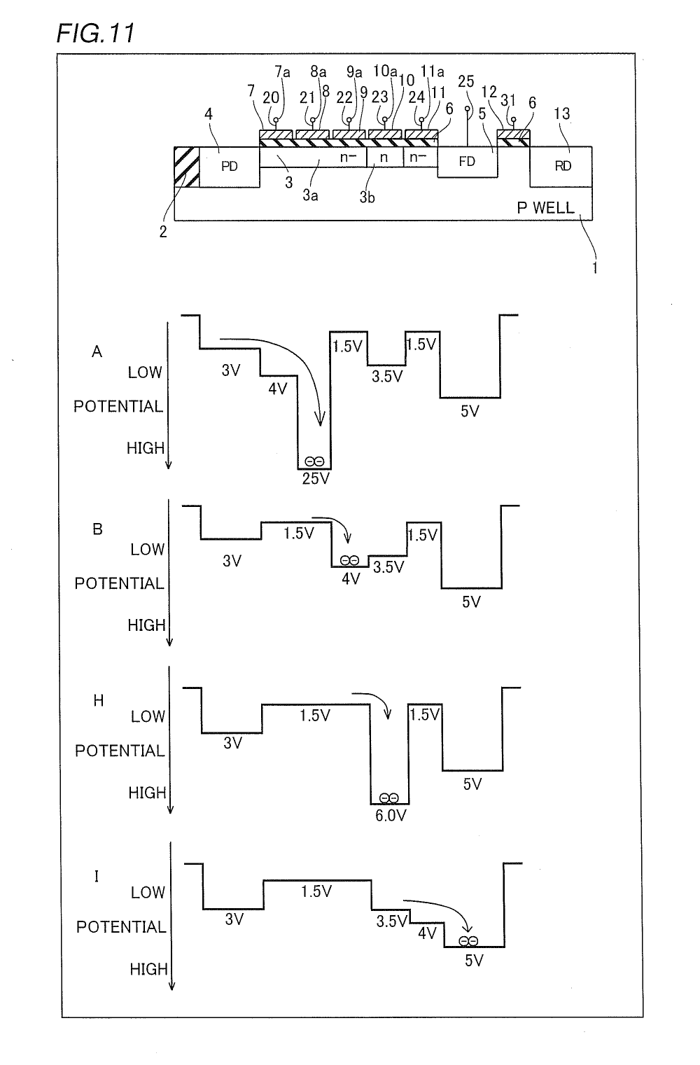

The electron transferring operation of the CMOS image sensor according to the second embodiment will be now described. As shown in FIGS. 10 and 11, an operation in periods A and B similar to that in the periods A and B of the aforementioned first embodiment is performed, thereby transferring electrons generated by a PD portion 4 to a region of a transfer channel 3 located under a transfer gate electrode 9. Then the storage gate electrode 10 is brought into an ON-state and the transfer gate electrode 9 is brought into an OFF-state in a period H. Thus, a region (electron storage portion 3b) of the transfer channel 3 located under the storage gate electrode 10 is controlled to a potential of about 6 V, and the region of the transfer channel 3 located under the transfer gate electrode 9 is thereafter controlled to a potential of about 1.5 V. Then the electrons having been transferred to the region of the transfer channel 3 located under the transfer gate electrode 9 are transferred to the electron storage portion 3b having a higher potential. In a period I, a read gate electrode 11 is brought into an ON-state and the storage gate electrode 10 is brought into an OFF-state, to control a region of the transfer channel 3 located under the read gate electrode 11 to a potential of about 4 V and to thereafter control the region of the transfer channel 3 located under the storage gate electrode 10 to a potential of about 3.5 V. Thus, the electrons having been transferred to the electron storage portion 3b are transferred to the FD region 5 through the region of the transfer channel 3 located under the read gate electrode 11. Thus, the electron transferring operation is completed.

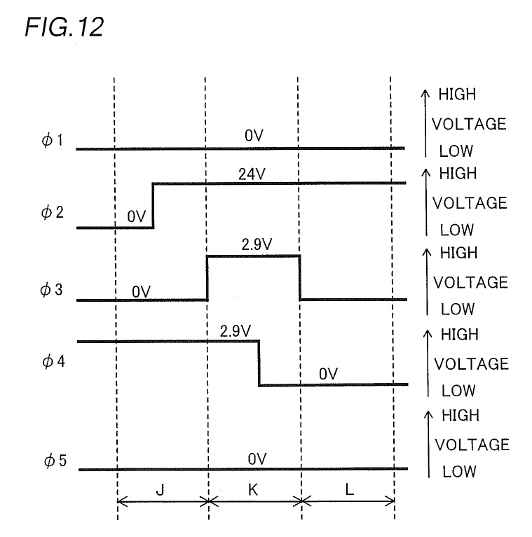

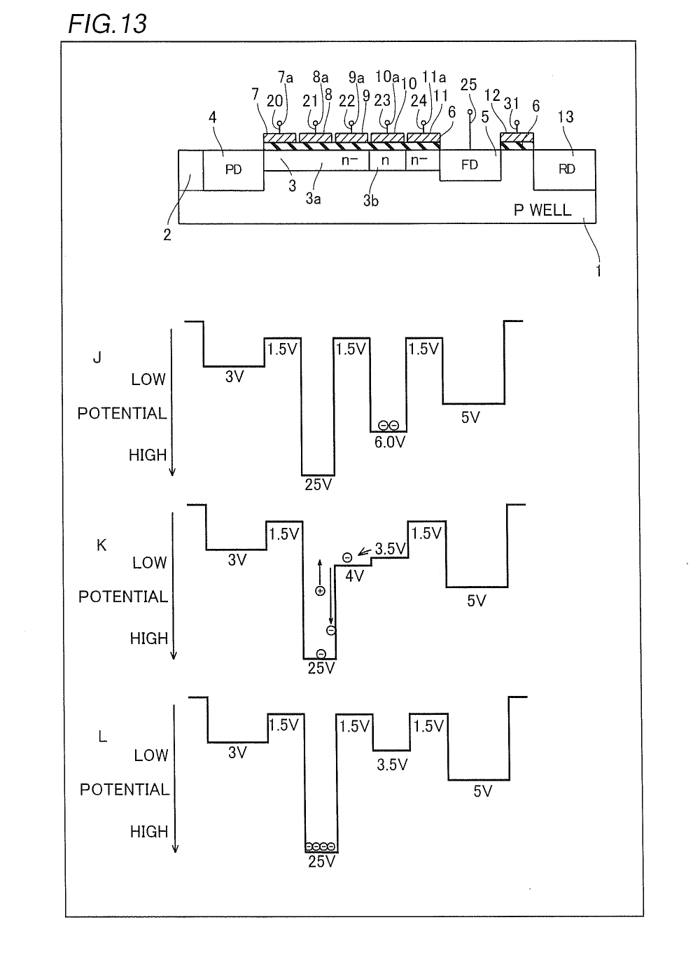

The electron multiplying operation of the CMOS image sensor according to the second embodiment will be now described. As shown in FIGS. 12 and 13, the operation in the periods A and B of the aforementioned first and second embodiments and the period H is performed, thereby bringing the storage gate electrode 10 into an ON-state to store electrons in the electron storage portion 3b under the storage gate electrode 10. At this time, the multiplier gate electrode 8 is brought into an ON-state to control the electron multiplying portion 3a under the multiplier gate electrode 8 to a potential of about 25 V in a period J. Then the transfer gate electrode 9 is brought into an ON-state and the storage gate electrode 10 is thereafter brought into an OFF-state in a period K. Thus, the region of the transfer channel 3 located under the transfer gate electrode 9 is controlled to a potential of about 4 V and the electron storage portion 3b under the storage gate electrode 10 is controlled to a potential of about 3.5 V. Thus, electrons are transferred from the electron storage portion 3b to the electron multiplying portion 3a through the region of the transfer channel 3 located under the transfer gate electrode 9. In a period L, the transfer gate electrode 9 is brought into an OFF-state to control the region of the transfer channel 3 located under the transfer gate electrode 9 to a potential of about 1.5 V. The electrons are transferred to the electron multiplying portion 3a to be multiplied.

Thus, the electron transferring and multiplying operations are performed by bringing the storage gate electrode 10 into the ON-state, according to the second embodiment. Similarly to the first embodiment, the operation in the periods A, B and H to L (transfer operation between the electron multiplying portion 3a and the electron storage portion 3b) is controlled to be performed a plurality of times (about 400 times, for example), thereby multiplying electrons transferred from the PD portion 4 to about 2000 times.

According to the second embodiment, as hereinabove described, the CMOS image sensor is so formed that electrons are stored by bringing the storage gate electrode 10 into the ON-state, whereby the electron storage portion 3b is maintained at a high potential due to an elevated concentration and hence a larger number of electrons can be held in the electron storage portion 3b. Therefore, electrons can be reliably held even when the electrons are multiplied to reach the larger number. At this time, the potential difference between the regions of the transfer channel 3 located under the transfer gate electrode 9 and the read gate electrode 11 supplied with the OFF-state signals and the electron storage portion 3b brought into the ON-state are larger than the potential difference between the regions of the transfer channel 3 located under the transfer gate electrode 9 and the read gate electrode 11 supplied with the OFF-state signals and the electron storage portion 3b in bringing the storage gate electrode 10 into the OFF-state. Therefore, the height of a potential barrier between the region of the transfer channel 3 located under the transfer gate electrode 9 and the electron storage portion 3b and the height of a potential barrier between the region of the transfer channel 3 located under the read gate electrode 11 and the electron storage portion 3b are relatively increased, and hence electrons can be reliably held in the electron storage portion 3b.

According to the aforementioned second embodiment, the potential (6 V) of the region of the transfer channel 3 located under the storage gate electrode 10 in bringing the storage gate electrode 10 into the ON-state is higher than the potentials (4 V) of the regions of the transfer channel 3 located under the transfer gate electrode 9 and the read gate electrode 11 in bringing the transfer gate electrode 9 and the read gate electrode 11 into the ON-states, and hence electrons can be easily held in the electron storage portion 3b also when the storage gate electrode 10 is brought into the ON-state.

Although the present invention has been described and illustrated in detail, it is clearly understood that the same is by way of illustration and example only and is not to be taken by way of limitation, the spirit and scope of the present invention being limited only by the terms of the appended claims.

For example, while each of the aforementioned first and second embodiments is applied to the active CMOS image sensor amplifying a charge signal in each pixel 50 as an exemplary image sensor, the present invention is not restricted to this but is also applicable to a passive CMOS image sensor not amplifying a charge signal in each pixel.

While the regions of the transfer channel 3 located under the transfer gate electrode 7, the transfer gate electrode 9 and the read gate electrode 11 are controlled to potentials of about 4 V when the transfer gate electrode 7, the transfer gate electrode 9 and the read gate electrode 11 are in the ON-states in each of the first and second embodiments, the present invention is not restricted to this but the regions of the transfer channel 3 located under the transfer gate electrode 7, the transfer gate electrode 9 and the read gate electrode 11 may be controlled to different potentials when the transfer gate electrode 7, the transfer gate electrode 9 and the read gate electrode 11 are in the ON-states. In this case, the potentials of the regions of the transfer channel 3 located under the transfer gate electrode 9 and the read gate electrode 11 in the ON-states must be controlled to be higher than that of the region of the transfer channel 3 located under the storage gate electrode 10 in the OFF-state.

While the transfer channel 3, the PD portion 4 and the FD region 5 are formed on the surface of the p-type well region 1 formed on the surface of the n-type silicon substrate (not shown) in each of the aforementioned first and second embodiments, the present invention is not restricted to this but the transfer channel 3, the PD portion 4 and the FD region 5 may be formed on the surface of the p-type silicon substrate.

While the electrons are employed as the signal charges in each of the aforementioned first and second embodiments, the present invention is not restricted to this but holes may alternatively be employed as the signal charges by entirely reversing the conductivity type of the substrate impurity and the polarities of the applied voltages.

While As (arsenic) is implanted so that the region of the transfer channel 3 located under the storage gate electrode 10 has a high concentration in each of the aforementioned first and second embodiments, the present invention is not restricted to this but an impurity or a dopant other than As (arsenic) may be implanted.

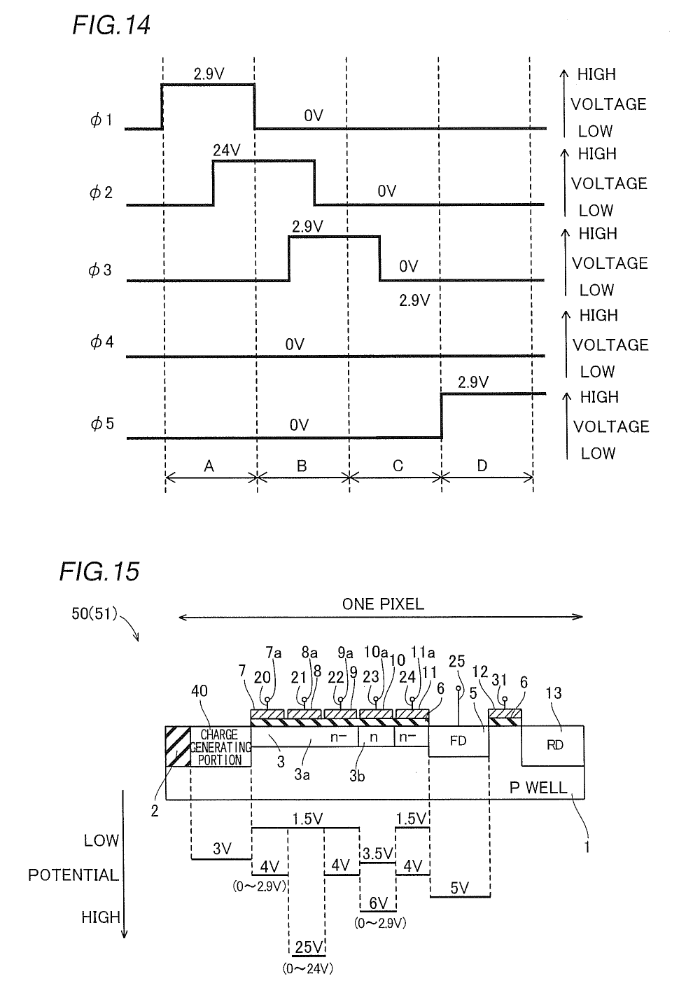

While the ON-state voltage is applied to the region (electron multiplying portion 3a) of the transfer channel 3 located under the multiplier gate electrode 8 and the ON-state voltage is applied to the transfer gate electrode 7 to transfer electrons when transferring the electrons from the PD portion 4 in each of the aforementioned first and second embodiments, the present invention is not restricted to this but ON-state voltages may be applied to the electrodes successively from the transfer gate electrode 7 to transfer electrons when transferring electrons from the PD portion 4. More specifically, an ON-state voltage is applied to the transfer gate electrode 7 to transfer electrons from the PD portion 4 to the region of the transfer channel 3 located under the transfer gate electrode 7 in a period A, as shown in FIG. 14. Thereafter an ON-state voltage is applied to the multiplier gate electrode 8 and an OFF-state voltage is thereafter applied to the transfer gate electrode 7, to transfer electrons from the region of the transfer channel 3 located under the transfer gate electrode 7 to the region of the transfer channel 3 located under the multiplier gate electrode 8. Thereafter electrons are controlled to be transferred from the region of the transfer channel 3 located under the transfer gate electrode 9 to the region of the transfer channel 3 located under the read gate electrode 11 through the region of the transfer channel 3 located under the storage gate electrode 10 through an operation similar to the transfer operation in the first embodiment.

While each of the aforementioned first and second embodiments of the present invention is applied to the CMOS image sensor employed as an exemplary image sensor, the present invention is not restricted to this but is also applicable to a sensor unit, other than the image sensor, performing sensing by generating electrons. For example, the CMOS image sensor according to each of the first and second embodiments can alternatively be operated as a sensor unit by arranging a charge generating portion 40 in place of the PD portion 4 as in another modification of the first and second embodiments shown in FIG. 15, to attain effects similar to those of the aforementioned first and second embodiments with this structure. This sensor unit can also multiply generated electrons (sensed data) by performing operations similar to those of the CMOS image sensors of the aforementioned first and second embodiments.

What is claimed is:

1. An image sensor comprising:
a charge storage portion for storing and transferring signal charges;
a first electrode for storing the signal charges in said charge storage portion;
a second electrode for transferring the signal charges to said charge storage portion;
a voltage conversion portion for converting the signal charges to a voltage;
a third electrode provided between said first electrode and said voltage conversion portion for transferring the signal charges stored in said charge storage portion to said voltage conversion portion; and
an impurity region provided under at least said first electrode, said second electrode and said third electrode for forming a path through which the signal charges transfer, wherein
the impurity concentration of a region of said impurity region corresponding to a portion located under said first electrode is higher than the impurity concentration of a region of said impurity region corresponding to each of portions located under at least said second electrode and said third electrode.

2. The image sensor according to claim 1, further comprising:
a charge increasing portion for increasing the signal charges stored in said charge storage portion; and
a fourth electrode for forming an electric field increasing the signal charges on said charge increasing portion, wherein
said impurity region is provided also under said fourth electrode in addition to said first electrode, said second electrode and said third electrode, and the impurity concentration of said region of said impurity region corresponding to said portion located under said first electrode is higher than the impurity concentration of a region of said impurity region corresponding to a portion located under said fourth electrode.

3. The image sensor according to claim 2, further comprising:
a photoelectric conversion portion generating the signal charges by photoelectric conversion; and
a fifth electrode provided to be adjacent to said photoelectric conversion portion for forming an electric field for transferring the signal charges generated by said photoelectric conversion portion to said charge increasing portion, wherein
said impurity region is provided also under said fifth electrode in addition to said first electrode, said second electrode, said third electrode and said fourth electrode, and the impurity concentration of said region of said impurity region corresponding to said portion located under said first electrode is higher than the impurity concentration of a region of said impurity region corresponding to a portion located under said fifth electrode.

4. The image sensor according to claim 3, wherein
the potential of said region of said impurity region corresponding to said portion located under said first electrode is higher than the potential of said region of said impurity region corresponding to each of said portions located under said second electrode, said third electrode, said fourth electrode and said fifth electrode, when the same voltage is applied to said first electrode, said second electrode, said third electrode, said fourth electrode and said fifth electrode.

5. The image sensor according to claim 4, wherein
said regions of said impurity region corresponding to said portions located under said second electrode, said third electrode, said fourth electrode and said fifth electrode have the same impurity concentration.

6. The image sensor according to claim 5, wherein
said regions of said impurity region corresponding to said portions located under said second electrode, said third electrode, said fourth electrode and said fifth electrode have the same potential when the same voltage is applied to said second electrode, said third electrode, said fourth electrode and said fifth electrode.

7. The image sensor according to claim 3, wherein
said fourth electrode is arranged between said second electrode and said fifth electrode.

8. The image sensor according to claim 1, wherein
first and second voltages for rendering the potential of said region of said impurity region corresponding to said portion located under said first electrode lower than the potential of said region of said impurity region corresponding to said portion located under said third electrode are applied to said first electrode and said third electrode respectively, and
said second voltage is applied to said third electrode in a state where said first voltage is applied to said first electrode, to transfer the signal charges stored in said charge storage portion through said region of said impurity region corresponding to said portion located under said third electrode to said voltage conversion portion.

9. The image sensor according to claim 8, wherein
said second voltage is higher than said first voltage and said first voltage is an OFF-state voltage.

10. The image sensor according to claim 9, wherein
said charge storage portion is provided on said region of said impurity region corresponding to said portion located under said first electrode, and
the signal charges are held in said charge storage portion in a state of applying said first voltage to said first electrode.

11. The image sensor according to claim 9, wherein
said first voltage is applied to said second electrode in a state of applying said first voltage to said first electrode, to transfer the signal charges from said region of said impurity region corresponding to said portion located under said second electrode to said charge storage portion.

12. The image sensor according to claim 9, wherein
an operation of transferring the signal charges from said photoelectric conversion portion to said voltage conversion portion through said impurity region is performed in a state of applying said first voltage to said first electrode.

13. The image sensor according to claim 9, wherein
said charge storage portion is provided on said region of said impurity region corresponding to said portion located under said first electrode, and
the signal charges are held in said charge storage portion in a state of applying said second voltage to said first electrode.

14. The image sensor according to claim 13, wherein
the potential of said charge storage portion in applying said second voltage to said first electrode is higher than the potential of said region of said impurity region corresponding to each of said portions located under said second electrode and said third electrode in applying said second voltage to said second electrode and said third electrode.

15. The image sensor according to claim 1, further comprising:
a charge increasing portion for increasing the signal charges stored in said charge storage portion; and
a fourth electrode for forming an electric field increasing the signal charges on said charge increasing portion, wherein
first and second voltages for rendering the potential of said region of said impurity region corresponding to said portion located under said first electrode lower than the potential of said region of said impurity region corresponding to said portion located under said second electrode are applied to said first electrode and said second electrode respectively, and
said second voltage is applied to said second electrode and a third voltage for forming an electric field increasing the signal charges on said charge increasing portion is applied to said fourth electrode in a state of applying said first voltage to said first electrode, to transfer the signal charges stored in said charge storage portion to said charge increasing portion through said region of said impurity region corresponding to said portion located under said second electrode.

16. The image sensor according to claim 15, wherein
the signal charges are increased on said charge increasing portion by impact ionization.

17. The image sensor according to claim 15, wherein
a signal charge increasing operation by transferring the signal charges from said charge storage portion to said charge increasing portion and a signal charge transferring operation from said charge increasing portion to said charge storage portion are alternately repeatedly performed in a state of applying said first voltage to said first electrode.

18. The image sensor according to claim 1, wherein
said impurity region is an n-type impurity region.

19. A sensor unit comprising:
a charge storage portion for storing and transferring signal charges;
a first electrode for storing the signal charges in said charge storage portion;
a second electrode for transferring the signal charges to said charge storage portion;
a voltage conversion portion for converting the signal charges to a voltage;
a third electrode provided between said first electrode and said voltage conversion portion for transferring the signal charges stored in said charge storage portion to said voltage conversion portion; and
an impurity region provided under at least said first electrode, said second electrode and said third electrode for forming a path through which the signal charges transfer, wherein
the impurity concentration of a region of said impurity region corresponding to a portion located under said first electrode is higher than the impurity concentration of a region of said impurity region corresponding to each of portions located under at least said second electrode and said third electrode.

20. A CMOS image sensor comprising:
a charge storage portion for storing and transferring signal charges;
a first electrode for storing the signal charges in said charge storage portion;
a second electrode for transferring the signal charges to said charge storage portion;
a voltage conversion portion for converting the signal charges to a voltage;
a third electrode provided between said first electrode and said voltage conversion portion for transferring the signal charges stored in said charge storage portion to said voltage conversion portion;
a charge increasing portion for increasing the signal charges stored in said charge storage portion; and
an impurity region provided under at least said first electrode, said second electrode and said third electrode for forming a path through which the signal charges transfer, wherein
said first electrode, said second electrode, said third electrode and said charge increasing portion are provided in a pixel, and
the impurity concentration of a region of said impurity region corresponding to a portion located under said first electrode is higher than the impurity concentration of a region of said impurity region corresponding to each of portions located under at least said second electrode and said third electrode.
